(19) United States
(12) Patent Application Publication
(10) Pub. No.: US 2010/0085680 A1
(43) Pub. Date: Apr. 8, 2010

(54) CRYSTALLINE ENCAPSULANTS

(75) Inventor: John D. Summers, Chapel Hill, NC (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/514,823

(22) PCT Filed: Dec. 11, 2007
(86) PCT No.: PCT/US2007/025297

§ 371 Date: May 14, 2009

Related U.S. Application Data
(60) Provisional application No. 60/874,667, filed on Dec. 12, 2006.

(51) Int. Cl. H01G 4/224; C08G 69/26; H01L 21/56

(52) U.S. Cl. 361/301.3; 524/606; 264/272.11; 264/272.13

(57) ABSTRACT

This invention relates to compositions, and the use of such compositions for protective coatings, particularly of electronic devices. The invention concerns fired-on-foil ceramic capacitors coated with a composite encapsulant and embedded in a printed wiring board.

### FIELD OF THE INVENTION

This invention relates to compositions, and the use of such compositions for protective coatings. In one embodiment, the compositions are used to protect electronic device structures, particularly embedded fired-on-foil ceramic capacitors, from exposure to printed wiring board processing chemicals and for environmental protection.

### TECHNICAL BACKGROUND OF THE INVENTION

Electronic circuits require passive electronic components such as resistors, capacitors, and inductors. A recent trend is for passive electronic components to be embedded or integrated into the organic printed circuit board (PCB). The practice of embedding capacitors in printed circuit boards allows for reduced circuit size and improved circuit performance. Embedded capacitors, however, must meet high reliability requirements along with other requirements, such as high yield and performance. Meeting reliability requirements involves passing accelerated life tests. One such accelerated life test is exposure of the circuit containing the embedded capacitor to 1000 hours at 85% relative humidity, 85° C. under 5 volts bias. Any significant degradation of the insulation resistance would constitute failure.

High capacitance ceramic capacitors embedded in printed circuit boards are particularly useful for decoupling applications. High capacitance ceramic capacitors may be formed by “fired-on-foil” technology. Fired-on-foil capacitors may be formed from thick-film processes as disclosed in U.S. Pat. No. 6,317,023B1 to Felten or thin-film processes as disclosed in U.S. Patent Application 20050011857 A1 to Borland et al.

Thick-film fired-on-foil ceramic capacitors are formed by depositing a thick-film capacitor dielectric material layer onto a metallic foil substrate, followed by depositing a top copper electrode material over the thick-film capacitor dielectric layer and a subsequent firing under copper thick-film firing conditions, such as 900-950° C. for a peak period of 10 minutes in a nitrogen atmosphere.

The capacitor dielectric material should have a high dielectric constant (K) after firing to allow for manufacture of small high capacitance capacitors suitable for decoupling. A high K thick-film capacitor dielectric is formed by mixing a high dielectric constant powder (the “functional phase”) with a glass powder and dispersing the mixture into a thick-film screen-printing vehicle.

During firing of the thick-film dielectric material, the glass component of the dielectric material softens and flows before the peak firing temperature is reached, coalesces, encapsulates the functional phase, and finally forms a monolithic ceramic/copper electrode film.

The foil containing the fired-on-foil capacitors is then laminated to a prepreg dielectric layer, capacitor component face down to form an inner layer and the metallic foil may be etched to form the foil electrodes of the capacitor and any associated circuitry. The inner layer containing the fired-on-foil capacitors may now be incorporated into a multilayer printed wiring board by conventional printing wiring board methods.

The fired ceramic capacitor layer may contain some porosity and, if subjected to bending forces due to poor handling, may sustain some microcracks. Such porosity and microcracks may allow moisture to penetrate the ceramic structure and when exposed to bias and temperature in accelerated life tests may result in low insulation resistance and failure.

In the printed circuit board manufacturing process, the foil containing the fired-on-foil capacitors may also be exposed to caustic stripping photoresist chemicals and a brown or black oxide treatment. This treatment is often used to improve the adhesion of copper foil to prepreg. It consists of multiple exposures of the copper foil to caustic and acid solutions at elevated temperatures. These chemicals may attack and partially dissolve the capacitor dielectric glass and dopants. Such damage often results in ionic surface deposits on the dielectric that results in low insulation resistance when the capacitor is exposed to humidity. Such degradation also compromises the accelerated life test of the capacitor.

It is also important that, once embedded, the encapsulated capacitor maintain its integrity during downstream processing steps such as the thermal excursions associated with solder reflow cycles or overmold baking cycles. Delaminations and/or cracks occurring at any of the various interfaces of the construction or within the layers themselves could undermine the integrity of the embedded capacitor by providing an avenue for moisture penetration into the assembly.

An approach to solve these issues is needed. Various approaches to improve embedded passives have been tried. An example of an encapsulant composition used to reinforce embedded resistors may be found in U.S. Pat. No. 6,860,000, issued to Felten.

### SUMMARY OF THE INVENTION

The invention concerns a fired-on-foil ceramic capacitor coated with an organic encapsulant that possesses a crystalline morphology and is embedded in a printed wiring board. The encapsulant consists of a crystalline polyimide with a water absorption of 2% or less; optionally one or more of an electrically insulated fillers, a defoamer and a colorant and one or more organic solvents. The polyimide is chosen such that its poly(amic acid) precursor, polyisoimide precursor, or poly(amic ester) precursor is soluble in one or more conventional screen printing solvents. The polyimide also possesses a melting point greater than 300° C.

Compositions are disclosed comprising: a poly(amic acid), polyisoimide, or poly(amic ester), optionally one or more electrically insulated fillers, defoamers and colorants and an organic solvent. The compositions have a consolidation temperature of about 450° C. or less.

The invention is also directed to a method of encapsulating a fired-on-foil ceramic capacitor with an encapsulant, the encapsulant comprising a crystalline polyimide with a water absorption of 2% or less; optionally one or more electrically insulated fillers, defoamers and colorants and an organic solvent. The encapsulant is then cured at a temperature equal to or less than about 450° C.

The inventive compositions containing the organic materials can be applied as an encapsulant to any other electronic component or mixed with inorganic electrically insulating fillers, defoamers, and colorants, and applied as an encapsulant to any electronic component.

According to common practice, the various features of the drawings are not necessarily drawn to scale. Dimensions of various features may be expanded or reduced to more clearly illustrate the embodiments of the invention.

### BRIEF DESCRIPTION OF THE DRAWINGS

FIG. 1A through 1G show the preparation of capacitors on commercial 96% alumina substrates that were covered by the composite encapsulant compositions and used as a test vehicles to determine the composite encapsulant's resistance to selected chemicals.

FIG. 2A-2E show the preparation of capacitors on copper foil substrates that were covered by encapsulant.

FIG. 2F shows a plan view of the structure.

FIG. 2G shows the structure after lamination to resin.

### DETAILED DESCRIPTION OF THE INVENTION

The present invention provides an unexpected, novel, superior encapsulant composition that allows for screen printing and the formation of a crystalline polyimide encapsulant. Thus, allows for an embedded capacitor comprising a superior encapsulant and superior properties.

The present invention provides a thick film encapsulant composition comprising (1) a crystalline polyimide precursor selected from the group consisting of poly(amic acid), polyisoimide, poly(amic ester) and mixtures thereof and (2) an organic solvent.

A fired-on-foil ceramic capacitor coated with a crystalline encapsulant and embedded in a printed wiring board is disclosed. The application and processing of the encapsulant is designed to be compatible with printed wiring board and integrated circuit (IC) package processes. It also provides protection to the fired-on-foil capacitor from moisture, printed wiring board fabrication chemicals prior to and after embedding into the structure, and accommodates mechanical stresses generated by localized differences in relative thermal expansion coefficients of the capacitor element and organic components without delaminating. Application of said composite encapsulant to the fired-on-foil ceramic capacitor allows the capacitor embedded inside the printed wiring board to pass 1000 hours of accelerated life testing conducted at 85° C., 85% relative humidity under 5 volts of DC bias.

Encapsulant compositions are disclosed comprising:

A soluble poly(amic acid), polyisoimide, poly(amic ester) or mixtures thereof that yields a crystalline polyimide upon heating (or other processing means including microwave, light, laser) to a sufficient temperature, an organic solvent, and optionally one or more of an inorganic electrically insulating filler, a defoamer and a colorant dye. The amount of water absorption is determined by ASTM D-570, which is a method known to those skilled in the art.

Applicants determined that the most stable polymer matrix is achieved with the use of polyimides that also have low moisture absorption of 2% or less, preferably 1.5% or less, more preferably 1% or less. Polymers used in the compositions with water absorption of 1% or less tend to provide consolidated materials with preferred protection characteristics.

Crystalline Polyimide

Generally, the polyimide component of the present invention can be represented by the general formula:

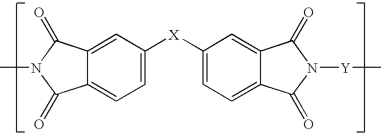

where X can be equal to a chemical bond (90-100 mole %), or a chemical bond used in combination with minor amounts of other bridging units (less than about 10 mole %) such as C(CF₃)₂, SO₂, O, C(CF₃)phenyl, C(CF₃)CF₂CF₃, C(CF₂CF₃)phenyl; and where Y is derived from a diamine component comprising 4,4′-diamino-2,2′-bis(trifluoromethyl)biphenyl (TFMB) or bis(trifluoromethoxy)benzidine (TFMOB). These can be used alone or in combination with one another or in combination with minor amounts of the following diamines: 3,4′-diaminodiphenyl ether (3,4′-ODA), 3,3′,5,5′-tetramethylbenzidine, 2,3,5,6-tetramethyl-1,4-phenylenediamine, 3,3′-diaminodiphenyl sulfone, 3,3′dimethylbenzidine, 3,3′-bis(trifluoromethyl)benzidine, 2,2′-bis-(p-aminophenyl)hexafluoropropane, 2,2′-bis(pentafluoroethoxy)benzidine (TFEOB), 2,2′-trifluoromethyl-4,4′-oxydianiline (OBABTF), 2-phenyl-2-trifluoromethyl-bis(p-aminophenyl)methane, 2-phenyl-2-trifluoromethyl-bis(m-aminophenyl)methane, 2,2′-bis(2-heptafluoroisopropoxy-tetrafluoroethoxy)benzidine (DFPOB), 2,2-bis(m-aminophenyl)hexafluoropropane (6-FmDA), 2,2-bis(3-amino-4-methylphenyl)hexafluoropropane, 3,6-bis(trifluoromethyl)-1,4-diaminobenzene (2TFMPDA), 1-(3,5-diaminophenyl)-2,2-bis(trifluoromethyl)-3,3,4,4,5,5,5-heptafluoropentane, 3,5-diaminobenzotrifluoride (3,5-DABTF), 3,5-diamino-5-(pentafluoroethyl)benzene, 3,5-diamino-5-(heptafluoropropyl)benzene, 2,2′-dimethylbenzidine (DMBZ), 2,2′,6,6′-tetramethylbenzidine (TMBZ), 3,6-diamino-9,9-bis(trifluoromethyl)xanthene (6FCDAM), 3,6-diamino-9-trifluoromethyl-9-phenylxanthene (3FCDAM), 3,6-diamino-9,9-diphenyl xanthene.

The crystalline polyimides of the present invention are chosen such that their corresponding precursors are soluble in screen printing solvents. Combinations of monomers containing biphenyl structures with one or more of the components containing fluorine moieties are particularly useful in the present invention.

Crystalline polyimides are not easily formulated into thick film pastes due to their limited solubility characteristics. While poly(amic acid), polyisoimide, and poly(amic ester) precursors to crystalline polyimides are soluble in dipolar aprotic solvents, their solubility in traditional screen printing solvent families such as extended alcohols, ethers and acetates has not been fully explored. Furthermore, dipolar aprotic solvents are not acceptable screen printing solvents. Therefore, the vast majority of crystalline polyimides and their corresponding poly(amic acid)s, polyisoimides, and poly(amic ester)s have not been generally regarded as potential candidates for thick film paste formulations.

A largely unexplored approach for incorporating polyimides into thick film formulations is through the isoimide intermediate. Poly(amic acid)s can be dehydrated chemically to preferentially form the corresponding polyisoimide. The isoimide will then rearrange to the thermodynamically favored imide moiety when it is subjected to sufficient heat. Since polyisoimides are generally soluble in a wide variety of solvents, this offers a novel method of preparing screen printable encapsulants that will ultimately insoluble polyimides. Of particular interest for encapsulant applications is concentrating on preparing and formulating polyisoimides that rearrange to yield crystalline polyimides. Crystalline polyimides generally possess low diffusion coefficients to moisture and gases, high degree of dimensional stability, high toughness, high melting temperatures, low to moderate CTE's, low water uptake, good adhesion. These properties make them good candidates for embedded organic encapsulants.

The polyimides of the invention are prepared by reacting a suitable dianhydride (or mixture of suitable dianhydrides, or the corresponding diacid-diester, diacid halide ester, or tetracarboxylic acid thereof) with one or more selected diamines. The mole ratio of dianhydride component to diamine component is preferably from between 0.9 to 1.1. Preferably, a slight molar excess of dianhydrides or diamines can be used at mole ratio of about 1.01 to 1.02. End capping agents, such as phthalic anhydride, can be added to control chain length of the polyimide.

One dianhydride found to be useful in the practice of the present invention is biphenyl dianhydride, alone or in combination with minor amounts of other dianhydrides such as 3,3′,4,4′-diphenylsulfone tetracarboxylic dianhydride (DSDA), 2,2-bis(3,4-dicarboxyphenyl)1,1,1,3,3,3-hexafluoropropane dianhydride (6-FDA), 1-phenyl-1,1-bis(3,4-dicarboxyphenyl)-2,2,2-trifluoroethane dianhydride, 1,1,1,3,3,4,4,4-octylfluoro-2,2-bis(3,4-dicarboxyphenyl)butane dianhydride, 1-phenyl-2,2,3,3,3-pentafluoro-1,1-bis(3,4-dicarboxyphenyl)propane dianhydride, 4,4′-oxydiphthalic anhydride (ODPA), 2,2′-bis(3,4-dicarboxyphenyl)propane dianhydride, 2,2′-bis(3,4-dicarboxyphenyl)-2-phenylethane dianhydride, 2,3,6,7-tetracarboxy-9-trifluoromethyl-9-phenylxanthene dianhydride (3FCDA), 2,3,6,7-tetracarboxy-9,9-bis(trifluoromethyl)xanthene dianhydride (6FCDA), 2,3,6,7-tetracarboxy-9-methyl-9-trifluoromethylxanthene dianhydride (MTXDA), 2,3,6,7-tetracarboxy-9-phenyl-9-methylxanthene dianhydride (MPXDA), 2,3,6,7-tetracarboxy-9,9-dimethylxanthene dianhydride (NMXDA).

The thick film compositions comprise an organic solvent. The choice of solvent or mixtures of solvents will depend in-part on the resins used in the composition. Any chosen solvent or solvent mixtures must dissolve the crystalline polyimide precursor and the corresponding monomers used to prepare this intermediate. The solvent must also not interfere with the polymerization reaction between diamines and dianhydrides. As such, solvents containing alcohol groups are not recommended. Solvents known to be useful in accordance with the practice of the present invention include organic liquids having both (i.) a Hanson polar solubility parameter between about 5 and 8 and (ii) a normal boiling point ranging from between and including any two of the following numbers 190, 200, 210, 220, 230, 240, and 250. In one embodiment of the present invention, a useful solvent is butyrolactone. Cosolvents may be added provided that the composition is still soluble, performance in screen-printing is not adversely affected, and lifetime storage is also not adversely affected.

Generally, thick-film compositions are mixed and then blended on a three-roll mill. Pastes are typically roll-milled for three or more passes at increasing levels of pressure until a suitable dispersion has been reached. After roll milling, the pastes may be formulated to printing viscosity requirements by addition of solvent.

Curing of the paste or liquid composition is accomplished by any number of standard curing methods including convection heating, forced air convection heating, vapor phase condensation heating, conduction heating, infrared heating, induction heating, or other techniques known to those skilled in the art. These pastes can be cured at temperatures not exceeding about 450° C. High temperatures, above about 350° C., are preferred to fully convert the soluble intermediate to the polyimide structure and to develop the crystalline morphology.

Procedures used in the testing of the compositions of the invention and for the comparative examples are provided as follows:

Insulation Resistance

Insulation resistance of the capacitors is measured using a Hewlett Packard high resistance meter.

Temperature Humidity Bias (THB) Test

THB Test of ceramic capacitors embedded in printed wiring boards involves placing the printed wiring board in an environmental chamber and exposing the capacitors to 85° C., 85% relative humidity and a 5 volt DC bias. Insulation resistance of the capacitors is monitored every 24 hours. Failure of the capacitor is defined as a capacitor showing less than 50 meg-ohms in insulation resistance.

Brown Oxide Test

A capacitor is exposed to a MacDermid brown oxide treatment in the following series of steps: (1) 60 sec. soak in a solution of 4-8% H₂SO₄ at 40° C., (2) 120 sec. soak in deionized water at room temperature, (3) 240 sec. soak in a solution of 3-4% NaOH with 5-10% amine at 60° C., (4) 120 sec. soak in deionized water at room temperature, (5) 120 sec. soak in a solution of 20 ml/l H₂O₂ and H₂SO₄ acid with additive at 40° C., (6) a soak for 120 sec. in a solution made by mixing 280 ml of MacDermid Part A chemical solution diluted in 1 liter of DI water plus 40 ml of MacDermid Part B chemical solution diluted in 1 liter of DI water at 40° C., and (7) a deionized water soak for 480 sec. at room temperature. Insulation resistance of the capacitor is then measured after the exposure steps. Failure is defined as a capacitor showing less than 10 Meg-Ohms in insulation resistance.

### Encapsulant Film Moisture Absorption Test

The ASTM D570 method is used where polyimide solution is coated with a 20-mil doctor knife on a one oz. copper foil substrate. The wet coating is dried at 190° C. for about 1 hour in a forced draft oven to yield a polyimide film of 2 mils thickness. In order to obtain a thickness of greater than 5 mils as specified by the test method, two more layers are coated on top of the dried polyimide film with a 30 min 190° C. drying in a forced draft oven between the second and third coating. The three layer coating is dried 1 hr at 190° C. in a forced draft oven and then is dried in a 190° C. vacuum oven with a nitrogen purge for 16 hrs or until a constant weight is obtained. The polyimide film is removed from the copper substrate by etching the copper using commercially available acid etch technology. Samples of one inch by 3-inch dimensions are cut from the free-standing film and dried at 120° C. for 1 hour. The strips are weighed and immersed in deionized water for 24 hrs. Samples are blotted dry and weighed to determine the weight gain so that the percent water absorption can be calculated. Film samples were also placed in an 85/85 chamber for 48 hours to measure the water uptake of the samples under these conditions.

The following glossary contains a list of names and abbreviations for each ingredient used:

| | |
|---|---|
| BPDA | biphenyl dianhydride |
| TFMB | 4,4′-diamino-2,2′- |
| | bis(trifluoromethyl)biphenyl |
| GBL | gamma-butyrolactone |

### Example 1

### Poly(Amic Acid) Paste Production

A poly(amic acid) paste was prepared by the following method: To a dry three neck round bottom flask equipped with nitrogen inlet, mechanical stirrer and condenser was added 250 grams of dry high purity GBL, and 32.653 grams of 3,3′-bis-(trifluoromethyl)benzidine (TFMB).

To this stirred solution was added over one hour 30,000 grams of biphenyl dianhydride (BPDA). The solution of polyamic acid reached a temperature of 33° C. and was stirred without heating for 24 hrs during which time the dianhydride gradually dissolved and the polymer solution became viscous. After 24 hr. the viscosity of the poly(amic acid) solution was determined to be 50 Pa·S. This solution was used directly as a polymer thick film paste without further modification.

### Example 2

### Preparation of Ceramic Coupons Containing Encapsulated Ceramic Capacitors, Analysis of Chemical Stability of Encapsulant

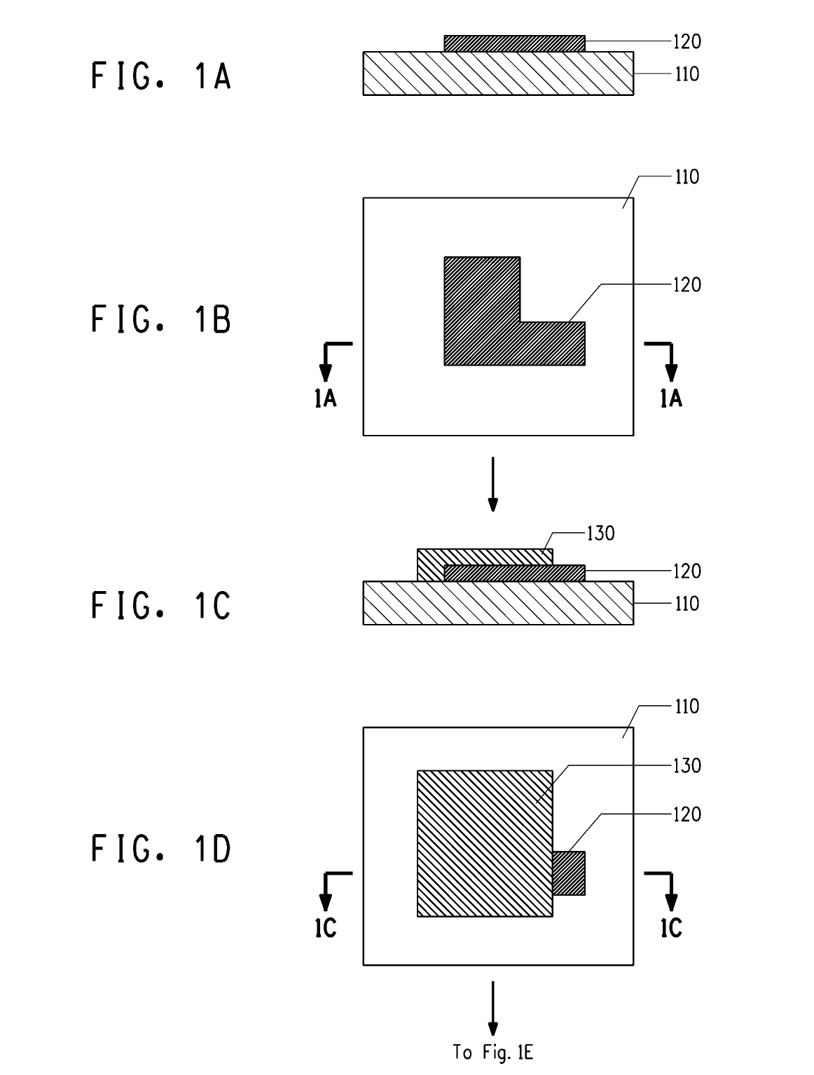

Capacitors on commercial 96% alumina substrates were covered by encapsulant compositions and used as a test vehicle to determine the encapsulant's resistance to selected chemicals. The test vehicle was prepared in the following manner as schematically illustrated in FIG. 1A through 1G.

As shown in FIG. 1A, electrode material (EP 320 obtainable from E. I. du Pont de Nemours and Company) was screen-printed onto the alumina substrate to form electrode pattern 120. As shown in FIG. 1B, the area of the electrode was 0.3 inch by 0.3 inch and contained a protruding “finger” to allow connections to the electrode at a later stage. The electrode pattern was dried at 120° C. for 10 minutes and fired at 930° C. under copper thick-film nitrogen atmosphere firing conditions.

As shown in FIG. 1C, dielectric material (EP 310 obtainable from E.I. du Pont de Nemours and Company) was screen-printed onto the electrode to form dielectric layer 130. The area of the dielectric layer was approximately 0.33 inch by 0.33 inch and covered the entirety of the electrode except for the protruding finger. The first dielectric layer was dried at 120° C. for 10 minutes. A second dielectric layer was then applied, and also dried using the same conditions. A plan view of the dielectric pattern is shown in FIG. 1D.

As shown in FIG. 1E, copper paste EP 320 was printed over the second dielectric layer to form electrode pattern 140. The electrode was 0.3 inch by 0.3 inch but included a protruding finger that extended over the alumina substrate. The copper paste was dried at 120° C. for 10 minutes.

The first dielectric layer, the second dielectric layer, and the copper paste electrode were then co-fired at 930° C. under copper thick-film firing conditions.

The encapsulant composition of Example 1 was screen printed through a 180 mesh screen over the entirety of the capacitor electrode and dielectric except for the two fingers using the pattern shown in FIG. 1F to form a 0.4 inch by 0.4 inch encapsulant layer 150. The encapsulant layer was dried for 10 minutes at 120° C. Another layer of encapsulant was printed with the formulation prepared in Example 1 through a 180 mesh screen directly over the first encapsulant layer and dried for 10 minutes at 120° C. A side view of the final stack is shown in FIG. 1G. The encapsulant was then baked under nitrogen in a forced draft oven at 190° C. for 30 minutes. The coupon was then cured in a multizone belt furnace under nitrogen atmosphere using the following profile:

| Parameter | Setting |
|---|---|
| Belt speed | 9 in/min |
| Zone 1 | 150° C. |
| Zone 2 | 170° C. |
| Zone 3 | 210° C. |
| Zone 4 | 240° C. |
| Zone 5 | 270° C. |
| Zone 6 | 300° C. |
| Zone 7 | 330° C. |
| Zone 8 | 360° C. |

The final cured thickness of the encapsulant was approximately 10 microns.

After encapsulation, the average capacitance of the capacitors was 42.3 nF, the average loss factor was 1.6%, the average insulation resistance was 3.1 Gohms. Coupons were then subjected to the brown oxide test described previously. The average capacitance, loss factor, and insulation resistance were 40.8 nf, 1.5%, 2.9 Gohm respectively after the treatment. Unencapsulated coupons did not survive the acid and base exposures.

### Example 3

### Preparation of Encapsulated Fired-On Foil Capacitors, Lamination with Prepreg and Core to Determine Adhesive Strength and Delamination Tendency

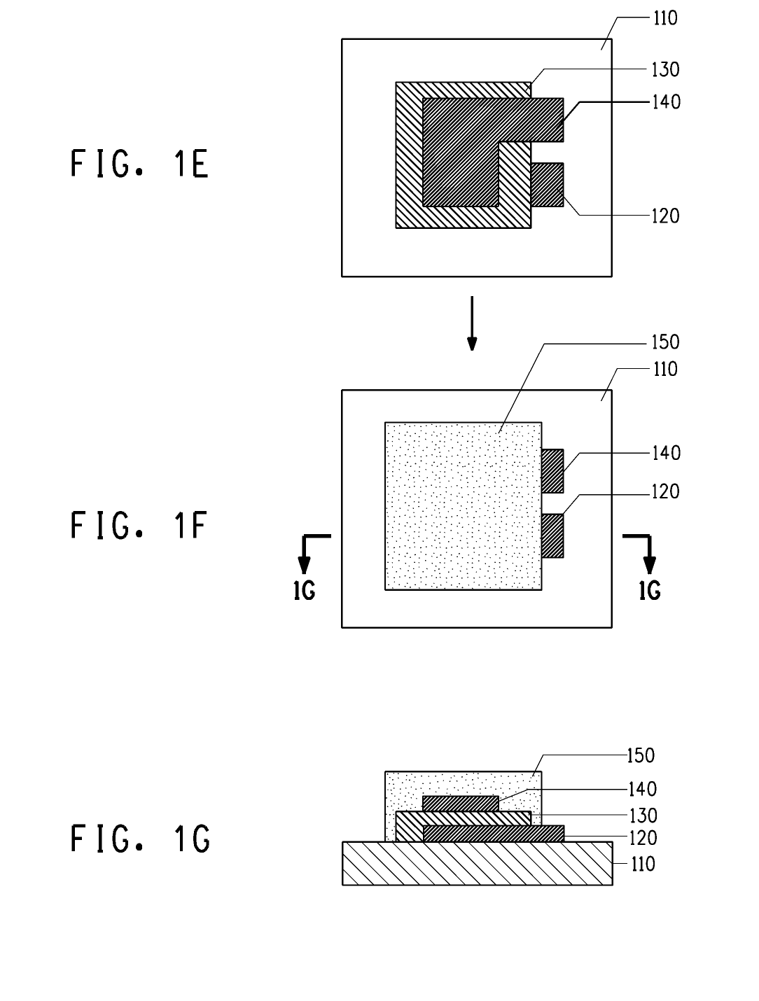

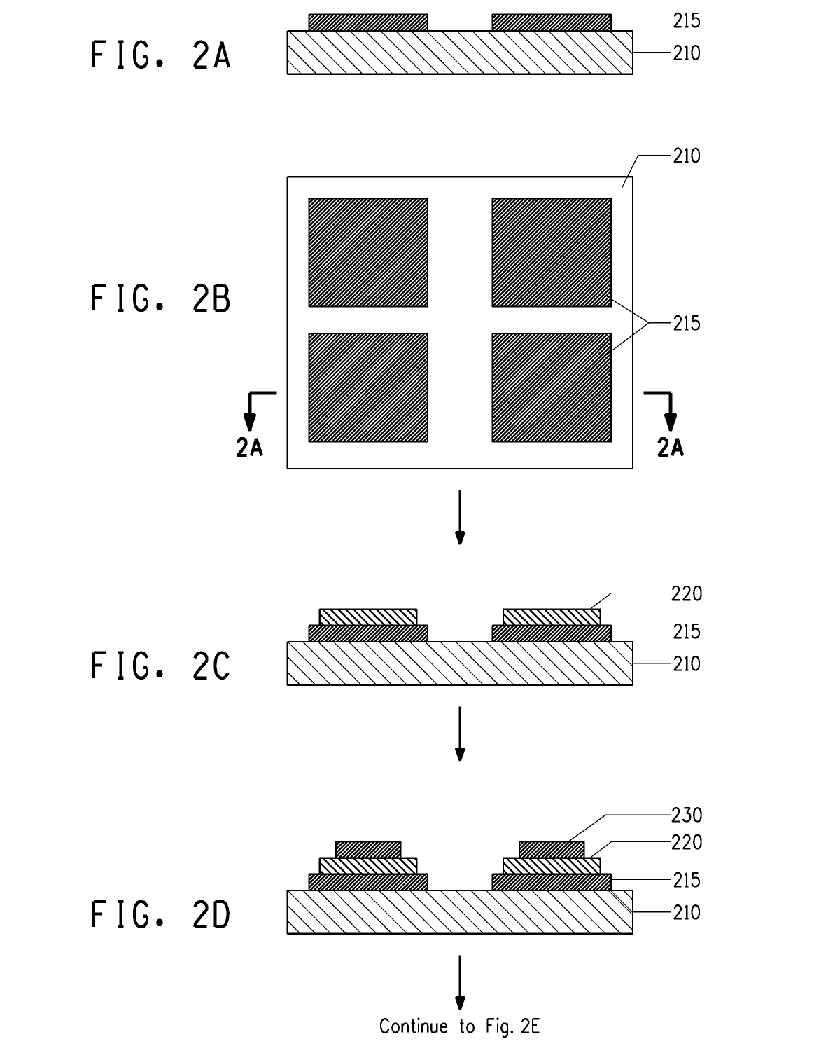

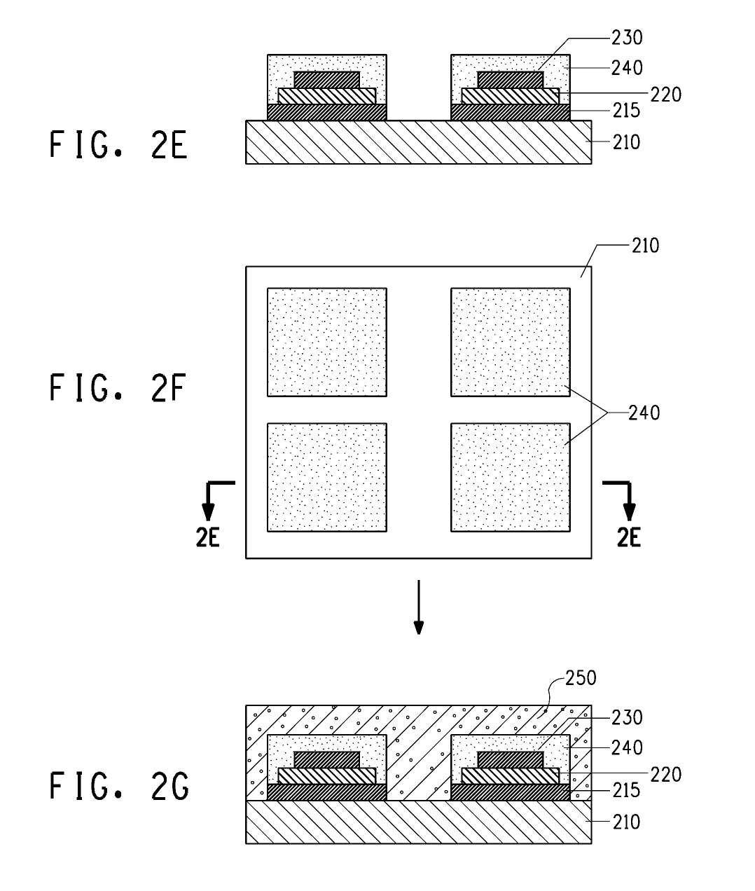

Fired-on-foil capacitors were fabricated for use as a test structure using the following process. As shown in FIG. 2A, a 1 ounce copper foil 210 was pretreated by applying copper paste EP 320 (obtainable from E. I. du Pont de Nemours and Company) as a preprint to the foil to form the pattern 215 and fired at 930° C. under copper thick-film firing conditions. Each preprint pattern was approximately 1.67 cm by 1.67 cm. A plan view of the preprint is shown in FIG. 2B.

As shown in FIG. 2c, dielectric material (EP 310 obtainable from E.I. du Pont de Nemours and Company) was screen-printed onto the preprint of the pretreated foil to form pattern 220. The area of the dielectric layer was 1.22 cm by 1.22.cm. and within the pattern of the preprint. The first dielectric layer was dried at 120° C. for 10 minutes. A second dielectric layer was then applied, and also dried using the same conditions.

As shown in FIG. 2D, copper paste EP 320 was printed over the second dielectric layer and within the area of the dielectric to form electrode pattern 230 and dried at 120° C. for 10 minutes. The area of the electrode was 0.9 cm by 0.9 cm.

The first dielectric layer, the second dielectric layer, and the copper paste electrode were then co-fired at 930° C. under copper thick-film firing conditions.

The encapsulant composition as described in Example 1 was printed through a 180 mesh screen over capacitors to form encapsulant layer 240 using the pattern as shown in FIG. 2E. The encapsulant was dried at 120° C. for ten minutes. A second encapsulant layer was then printed directly over the first layer using the paste prepared in Example 1 with a 180 mesh screen. The two-layer structure was then baked for 10 min at 120° C. then cured at 190° C. under nitrogen for 30 minutes to yield a consolidated two-layer composite encapsulant.

The foils were then cured in a multi-zone belt furnace under nitrogen atmosphere using the following profile:

| Parameter | Setting |
|---|---|
| Belt speed | 9 in/min |
| Zone 1 | 150° C. |
| Zone 2 | 170° C. |
| Zone 3 | 210° C. |
| Zone 4 | 240° C. |
| Zone 5 | 270° C. |
| Zone 6 | 300° C. |
| Zone 7 | 330° C. |
| Zone 8 | 360° C. |

The final cured encapsulant thickness was approximately 10 microns. A plan view of the structure is shown in FIG. 2F. The component side of the foil was laminated to 1080 BT resin prepreg 250 at 375° F. at 400 psi for 90 minutes to form the structure shown in FIG. 2G. The adhesion of the prepreg to the encapsulant was tested using the IPC-TM-650 adhesion test number 2.4.9. The adhesion results are shown below. Some foils were also laminated with 1080 BT resin prepreg and BT core in place of copper foil. These samples were subjected to 5 successive solder floats at 260° C., each exposure lasting three minutes, to determine the tendency for the structure to delaminate during thermal cycling. Visual inspection was used to determine if delamination occurred. Results are shown below:

| | | Encapsulant | Encapsulant |
|---|---|---|---|
| | | over Cu | over Capacitor |
| Dry Cycle | Cure Cycle | (lb force/inch) | (lb force/inch) |
| 120° C./10 min | 360° C. oven | 2.9 | 3.3 |

The failure mode was within the capacitor structure, not the encapsulant interface.

| Dry Cycle | Cure Cycle | Delamination |
|---|---|---|
| 120° C./10 min | 360° C. oven | no delamination after 5 cycles |

The control (no encapsulant) delaminated 30 seconds into the first solder float

### Example 4

### Preparation of Polyamic Ester

In a 2 liter round bottom flask with a mechanical stirrer, nitrogen inlet and condenser was added 572.35 grams of anhydrous DMAC, 2.386 grams of phthalic anhydride and 51.230 grams of 2,2′-bis(trifluoromethyl)benzidine (TFMB). To this solution was added 47.360 grams of 3,3′,4,4′-biphenyl tetracarboxylic dianhydride (BPDA) over 45 minutes without external heating. The yellow colored reaction mixture was stirred 16 hours at room temperature to yield a clear yellow solution. To this solution was added 36.255 grams of triethylamine in an addition funnel over 30 minutes, followed by the addition of 74.45 grams of trifluoroacetic anhydride in an addition funnel over 1.5 hours. The solution was heated to 45° C. for 2 hours. To the clear yellow solution was added 41.97 grams of anhydrous methanol and the solution was heated at 45° C. for 16 hours. The polyamic ester product was precipitated in DI water in a Waring blender, collected by filtration and the solid was blended two more times in DI water and filtered with the final filtrate having a pH of 5. The solid was vacuum oven dried at 100° C. for 2 days to yield 99.5 grams of dry polymer.

### Example 5

An encapsulant paste was prepared by dissolving 97.10 grams of the polyamic ester of Example 4 in 390.83 grams of Dowanol PPh at 80° C. over 5 hours in a resin kettle with nitrogen inlet, mechanical stirrer and a condenser. To this solution was added 0.245 grams of R0123 defoamer plus 2.60 grams of Dowanol PPh. After 30 minutes of stirring, the paste was cooled to room temperature and filtered under a pressure of 40 PSI through a Whatman Inc. (Newton Mass.) Polycap HD capsule filter with 0.2/0.345 micron pore size polypropylene filter media. The 19.8% solids paste had a viscosity of 50 PaS at 10 RPM.

### Example 6

Ceramic coupons prepared as outlined in Example 2 were used for this experiment. The encapsulant composition of Example 5 was screen printed through a 180 mesh screen over the entirety of the capacitor electrode and dielectric except for the two fingers using the pattern shown in FIG. 1F to form a 0.4 inch by 0.4 inch encapsulant layer. The encapsulant layer was dried for 10 minutes at 120° C. Another layer of encapsulant was printed with the formulation prepared in Example 5 through a 180-mesh screen directly over the first encapsulant layer and dried for 10 minutes at 120° C. A side view of the final stack is shown in FIG. 1G. The encapsulant 150 was then baked under nitrogen in a forced draft oven at 190° C. for 30 minutes. The coupon was then cured in a multizone belt furnace under nitrogen atmosphere using the following profile:

| Parameter | Setting |
|---|---|
| Belt speed | 9 in/min |
| Zone 1 | 150° C. |
| Zone 2 | 170° C. |
| Zone 3 | 210° C. |
| Zone 4 | 240° C. |
| Zone 5 | 270° C. |
| Zone 6 | 300° C. |
| Zone 7 | 330° C. |
| Zone 8 | 360° C. |

The final cured thickness of the encapsulant was approximately 10 microns.

After encapsulation, the average capacitance of the twenty capacitors was 61.2 nF/cm², the average loss factor was 2.2%, the average insulation resistance was 3.5 Gohms. The capacitors were then subjected to the Brown Oxide Test described previously. After the Brown Oxide Test treatment, the average capacitance, loss factor, and insulation resistance of the twenty capacitors were 62.3 nF/cm², 2.1%, and 3.2 Gohm, respectively. Unencapsulated coupons did not survive the Brown Oxide Test exposure.

The twenty encapsulated capacitors that were subjected to the Brown Oxide Test were next tested according to the Temperature Humidity Bias Test described above. The twenty capacitors were subjected to a 5V DC bias and placed in an 85° C./85% RH oven for 1000 hours after which time the capacitance, loss and insulation resistance were measured again. The twenty capacitors survived the 1000 hours of THB testing. The average capacitance, loss factor, and insulation resistance of the twenty capacitors were 60.2 nF/cm², 2.3%, and 1.1 Gohm respectively. One out of the twenty capacitors tested exhibited insulation resistance values below 10 Meg-ohm.

### Example 7

The foils described in Example 3 were used for this example. The encapsulant composition as described in Example 5 was printed through a 180-mesh screen over the capacitors to form an encapsulant layer. The encapsulant layer was dried at 120° C. for ten minutes. A second encapsulant layer was then printed directly over the first layer using the paste prepared in Example 5 with a 180-mesh screen. The two-layer structure was then dried for 10 min at 120° C. and then baked at 190° C. under nitrogen for 30 minutes to yield a consolidated two-layer composite encapsulant 240 having the pattern as shown in FIG. 2E. The coupon was then cured in a multizone belt furnace under nitrogen atmosphere using the following profile:

| Parameter | Setting |
|---|---|
| Belt speed | 9 in/min |
| Zone 1 | 150° C. |
| Zone 2 | 170° C. |
| Zone 3 | 210° C. |
| Zone 4 | 240° C. |
| Zone 5 | 270° C. |
| Zone 6 | 300° C. |
| Zone 7 | 330° C. |
| Zone 8 | 360° C. |

The final thickness of the baked encapsulant 240 was approximately 10 microns. A plan view of the structure is shown in FIG. 2F.

The component side of the foil 210 was laminated to 1080 BT resin prepreg 250 at 190° C. and 400 psi for 90 minutes to form the structure shown in FIG. 2G. In this example, one set of 16 fired-on-foil capacitors was produced on one piece of copper foil to be used for peel strength testing, and a second set of 16 fired-on-foil capacitors was produced on another piece of copper foil to be used for delamination testing.

The adhesion of the prepreg to the encapsulant was tested using the IPC-TM-650 adhesion test number 2.4.9. The adhesion results are shown below. The average peel strength of the encapsulant from the 16 capacitors was greater than 3.5 lbs/linear inch. The failure mode was within the capacitor structure, not the encapsulant interface.

The second set of 16 fired-on-foil capacitors was laminated with 1080 BT resin prepreg and BT core in place of copper foil. These capacitors were subjected to 5 successive solder floats at 260° C., each exposure lasting two minutes, to determine the tendency for the structure to delaminate during thermal cycling. Ultrasonic inspection was used to determine if delamination occurred. No delamination was observed after the five cycles.

### Comparative Example 1

### Preparation of an Amorphous Polyimide Encapsulant

A polyimide was prepared by conversion of a polyamic acid to polyimide with chemical imidization. To a dry three neck round bottom flask equipped with nitrogen inlet, mechanical stirrer and condenser was added 800.23 grams of DMAC, 70.31 grams of 3,3′-bis-(trifluoromethyl)benzidine (TFMB), 14.18 grams 2,2′-bis(3-amino-4-hydroxyphenyl)hexafluoropropane (6F-AP) and 0.767 grams of phthalic anhydride.

To this stirred solution was added over one hour 113.59 grams of 2,2′-bis-3,4-dicarboxyphenyl)hexafluoropropane dianhydride (6-FDA). The solution of polyamic acid reached a temperature of 32° C. and was stirred without heating for 16 hrs. To 104.42 grams of acetic anhydride were added followed by 95.26 grams of 3-picoline and the solution was heated to 80° C. for 1 hour.

The solution was cooled to room temperature, and the solution added to an excess of methanol in a blender to precipitate the product polyimide. The solid was collected by filtration and was washed 2 times by re-blending the solid in methanol. The product was dried in a vacuum oven with a nitrogen purge at 150° C. for 16 hrs to yield 165.6 grams of product having a number average molecular weight of 52,600 and a weight average molecular weight of 149,400.

A screen printable paste was prepared by dissolving 20 g of the isolated polyimide powder in 80 g DBE3. After the polymer dissolved, 1.8 g RSS-1407 epoxy resin (diglycidyl ether of tetramethyl biphenyl) and 0.2 g benzotriazole were added to the polymer solution. After these ingredients were dissolved, the crude paste was filtered under pressure through 0.2 micron cartridge filter to yield the final product.

### Comparative Example 2

### Performance of an Amorphous Polyimide Encapsulant

Ceramic coupons prepared as outlined in Example 2 were used for this experiment. The encapsulant composition of Comparative Example 1 was screen printed through a 180 mesh screen over the entirety of each capacitor electrode and dielectric except for the two fingers using the pattern shown in FIG. 1F to form a 0.4 inch by 0.4 inch encapsulant layer. The encapsulant layer was dried for 10 minutes at 120° C. Another layer of encapsulant was printed with the formulation prepared in Comparative Example 1 through a 180-mesh screen directly over the first encapsulant layer and dried for 10 minutes at 120° C. The encapsulant was then baked under nitrogen in a forced draft oven at 190° C. for 30 minutes. The final thickness of the encapsulant was approximately 10 microns.

After encapsulation, the average capacitance of the twenty capacitors was 64.1 nF/cm², the average loss factor was 2.3%, and the average insulation resistance was 3.9 Gohms. The coupon of twenty capacitors was then subjected to the Brown Oxide Test described previously. The average capacitance, loss factor, and insulation resistance were 62.8 nF/cm², 2.4%, 2.4 Gohm respectively after the treatment.

The twenty capacitors that had been subjected to the Brown Oxide Test were subsequently subjected to a 5V DC bias and placed in an 85° C./85% RH oven for 1000 hours, according to the THB Test, after which time the capacitance, loss and insulation resistance were measured again. Only seven out of 20 capacitors survived 1000 hours of testing. The average values capacitance, loss factor, and insulation resistance for the surviving capacitors were 59.8 nF/cm², 2.5%, and 0.8 Gohm, respectively. Thirteen capacitors out of 20 tested exhibited insulation resistance values below 10 Meg-ohm after 1000 hours exposure under 5V bias according to the THB Test.

The improved performance of the crystalline encapsulants prepared in Examples 1 and 5 is illustrated by this comparison.

What is claimed is:

1. A thick film encapsulant composition comprising (1) a crystalline polyimide precursor selected from the group consisting of poly(amic acid), polyisoimide, poly(amic ester) and mixtures thereof and (2) an organic solvent.

2. An organic crystalline encapsulant composition for coating embedded fired-on-foil ceramic capacitors in printed wiring boards and IC package substrates, wherein said embedded formed-on-foil ceramic capacitors comprise a capacitor and a prepreg.

3. The encapsulant composition of claim 1 composed of a crystalline polyimide with a water absorption of 2% or less and a melting temperature greater than 300° C.; optionally one or more of an electrically insulated filler, a defoamer, a colorant, and one or more organic solvents.

4. The encapsulant composition of claim 2 wherein polyamide precursors form said crystalline polyimide on heating and said polyamide precursors are selected from the group consisting of poly(amic acid) precursor, polyisoimide precursor, and poly(ester imide) precursors and wherein such polyamides are soluble in generally accepted screen printing solvents.

5. The composition of claim 1 comprising: a poly(amic acid), polyisoimide, or poly(amic ester), and, optionally, one or more electrically insulated fillers, defoamers and colorants and an organic solvent.

6. The encapsulant composition of claim 1 wherein said encapsulant composition, is cured to form a crystalline organic encapsulant and wherein said organic encapsulant provides protection to the capacitor when immersed in sulfuric acid or sodium hydroxide having concentrations of up to 30%.

7. The encapsulant composition of claim 1 wherein said encapsulant composition is cured to form a crystalline organic encapsulant and wherein the cured encapsulant provides protection to the capacitor in an accelerated life test of elevated temperatures, humidities and DC bias.

8. The encapsulant composition of claim 1 wherein said encapsulant composition is cured to form a cured crystalline organic encapsulant and wherein the water absorption is 1% or less.

9. The encapsulant composition of claim 1 wherein the composition can be cured at a temperature of less than or equal to 450° C.

10. The encapsulant composition of claim 1 wherein said encapsulant is cured to form a cured crystalline organic encapsulant and wherein the adhesion of said encapsulant to the capacitor and to the prepreg above the capacitor is greater than 2 lb force/inch.

11. The crystalline encapsulant composition of claim 1 wherein the circuit board containing encapsulated embedded cured-on-foil capacitors does not delaminate during elevated temperature thermal cycles.

12. A method of encapsulating a fired-on-foil ceramic capacitor with an encapsulant, the encapsulant comprising a crystalline polyimide with a water absorption of 2% or less; optionally one or more electrically insulated fillers, defoamers and colorants and an organic solvent.

13. The method of claim 12 where the encapsulant is cured at a temperature equal to or less than about 450° C.

15. The composition of claim 1 applied as an encapsulant to any electronic component.

16. The composition of claim 1 wherein said composition is mixed with inorganic electrically insulating fillers, defoamers, and colorants, and applied as an encapsulant to any electronic component.

17. A structure made by the method of claim 12.
